(19) United States
(12) Patent Application Publication
(10) Pub. No.: US 2026/0060019 A1
(43) Pub. Date: Feb. 26, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Ryuji YAMAMOTO, Toyama-shi (JP)

(73) Assignee: KOKUSAI ELECTRIC CORPORATION, Tokyo (JP)

(21) Appl. No.: 19/309,548

(22) Filed: Aug. 25, 2025

(30) Foreign Application Priority Data
Aug. 26, 2024 (JP) 2024-144371

(51) Int. Cl. H01L 21/311; H01J 37/32

(52) U.S. Cl. CPC H01L 21/31116; H01J 37/32449; H01J 2237/334

(57) ABSTRACT

There is provided a technique that includes: removing a third material by performing a cycle a predetermined number of times, the cycle including: providing a substrate subjected to processes including (a) exposing the substrate including a first material and the third material formed on a second material on a surface of the substrate to a modifying agent to allow an inhibitor contained in the modifying agent to be adsorbed on a surface of the first material and (b) exposing the substrate to a reactant to allow at least a portion of the third material to react with the reactant to generate a reaction product; and (c) applying energy to the substrate to perform removal of the reaction product and at least one selected from the group of removal and deactivation of the inhibitor in parallel.

### CROSS-REFERENCE TO RELATED APPLICATION

This application is based upon and claims the benefit of priority from Japanese Patent Application No. 2024-144371, filed on Aug. 26, 2024, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, a process of removing a specific material on a surface of a substrate is often performed.

### SUMMARY

Some embodiments of the present disclosure provide a technique capable of significantly shortening a processing time when selectively removing a specific material on a surface of a substrate.

According to some embodiments of the present disclosure, there is provided a technique that includes: removing a third material by performing a cycle a predetermined number of times, the cycle including: providing a substrate subjected to processes including (a) exposing the substrate including a first material and the third material formed on a second material on a surface of the substrate to a modifying agent to allow an inhibitor contained in the modifying agent to be adsorbed on a surface of the first material and (b) exposing the substrate to a reactant to allow at least a portion of the third material to react with the reactant to generate a reaction product; and (c) applying energy to the substrate to perform removal of the reaction product and at least one selected from the group of removal and deactivation of the inhibitor in parallel.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a processing apparatus suitably used in embodiments of the present disclosure, in which a portion of the process furnace is illustrated in a vertical sectional view.

FIG. 2 is a schematic configuration diagram of the vertical process furnace of the processing apparatus suitably used in embodiments of the present disclosure, in which the portion of the process furnace is illustrated in a cross-sectional view taken along line A-A in FIG. 1.

FIG. 3 is a schematic configuration diagram of a controller of a processing apparatus suitably used in embodiments of the present disclosure, in which a control system of the controller is illustrated in a block diagram.

FIG. 4A is a partial cross-sectional enlarged view showing a surface portion of a substrate according to embodiments of the present disclosure including a first material and a third material formed on a second material formed on a surface of the substrate. FIG. 4B is a partial cross-sectional enlarged view showing the surface portion of the substrate according to embodiments of the present disclosure after an inhibitor is adsorbed on the surface of the substrate by exposure to a modifying agent from a state shown in FIG. 4A. FIG. 4C is a partial cross-sectional enlarged view showing the surface portion of the substrate according to embodiments of the present disclosure after a portion of the third material is changed to a reaction product by exposure to a reactant from a state shown in FIG. 4B. FIG. 4D is a partial cross-sectional enlarged view showing the surface portion of the substrate according to embodiments of the present disclosure after the entire third material is changed to a reaction product by continuing the exposure to the reactant from a state shown in FIG. 4C. FIG. 4E is a partial cross-sectional enlarged view showing the surface portion of the substrate according to embodiments of the present disclosure after the inhibitor and the reaction product are removed from the surface by applying energy from a state shown in FIG. 4D.

FIG. 5A is a partial cross-sectional enlarged view showing a surface portion of a substrate according to a modification of the present disclosure before a first cycle is performed.

FIG. 5B is a partial cross-sectional enlarged view showing the surface portion of the substrate according to the modification of the present disclosure after an inhibitor is adsorbed on a surface of the substrate by exposure to a modifying agent from a state shown in FIG. 5A. FIG. 5C is a partial cross-sectional enlarged view showing the surface portion of the substrate according to the modification of the present disclosure after a portion of a third material is changed to a reaction product by exposure to a reactant from a state shown in FIG. 5B. FIG. 5D is a partial cross-sectional enlarged view showing the surface portion of the substrate according to the modification of the present disclosure after the inhibitor and the reaction product are removed from the surface of the substrate by applying energy from a state shown in FIG. 5C. FIG. 5E is a partial cross-sectional enlarged view showing the surface portion of the substrate according to the modification of the present disclosure before a second cycle is performed. FIG. 5F is a partial cross-sectional enlarged view showing the surface portion of the substrate according to the modification of the present disclosure after the inhibitor is adsorbed on the surface by exposure to the modifying agent from a state shown in FIG. 5E. FIG. 5G is a partial enlarged cross-sectional view showing the surface portion of the substrate according to the modification of the present disclosure after the entire remaining portion of the third material is changed to a reaction product by exposure to the reactant from a state shown in FIG. 5F. FIG. 5H is a partial enlarged cross-sectional view showing the surface portion of the substrate according to the modification of the present disclosure after the inhibitor and the reaction product are removed from the surface of the substrate by applying energy from a state shown in FIG. 5G.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

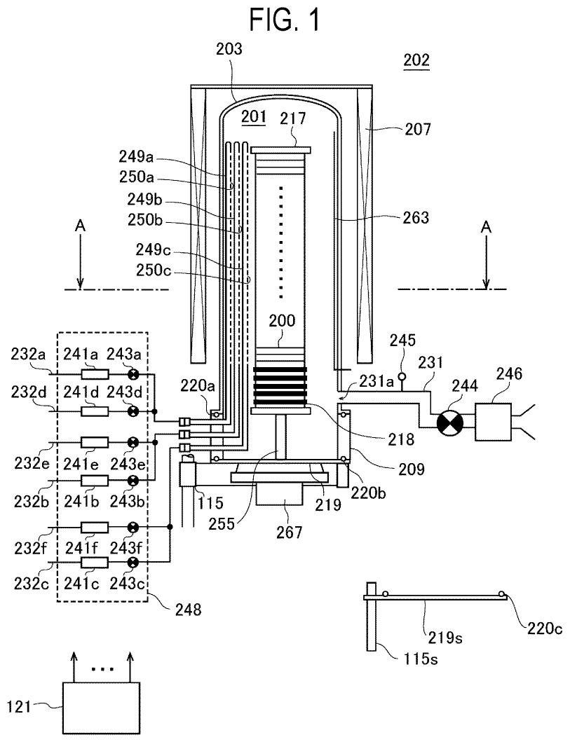

Hereinafter, embodiments of the present disclosure will be described mainly with reference to FIGS. 1 to 3 and 4A to 4E. The drawings used in the following description are schematic, and dimensional relationships, ratios, and the like of the respective components shown in the drawings may not match actual ones. Further, dimensional relationships, ratios, and the like of the respective components may not match one another among a plurality of drawings.

### (1) Configuration of Processing Apparatus

As shown in FIG. 1, a process furnace 202 of a processing apparatus includes a heater 207 as a temperature regulator (heating part). The heater 207 is formed in a cylindrical shape and is vertically installed by being supported by a holding plate. The heater 207 functions as an activator (an exciter) configured to activate (excite) a gas with heat. The heater 207 also functions as an energy applier configured to apply thermal energy to a substrate.

Inside the heater 207, a reaction tube 203 is arranged concentrically with the heater 207. The reaction tube 203 is made of, for example, a heat-resistant material such as quartz (SiO₂) or silicon carbide (SiC), and is formed in a cylindrical shape with its upper end closed and lower end opened. Under the reaction tube 203, a manifold 209 is arranged concentrically with the reaction tube 203. The manifold 209 is made of, for example, a metallic material such as stainless steel (SUS), and is formed in a cylindrical shape with its upper and lower ends opened. The upper end of the manifold 209 is engaged with the lower end of the reaction tube 203 so as to support the reaction tube 203. An O-ring 220a as a seal is provided between the manifold 209 and the reaction tube 203. Similar to the heater 207, the reaction tube 203 is installed vertically. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. The wafers 200 are processed in the process chamber 201.

Nozzles 249a to 249c as first to third suppliers are installed in the process chamber 201 so as to penetrate a side wall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The nozzles 249a to 249c are different nozzles, and the nozzles 249a and 249c are respectively installed adjacent to the nozzle 249b.

At the gas supply pipes 232a to 232c, mass flow controllers (MFCs) 241a to 241c, which are flow rate controllers (flow control parts), and valves 243a to 243c, which are on-off valves, are respectively installed sequentially from the upstream side of a gas flow. A gas supply pipe 232d is connected to the gas supply pipe 232a on the downstream side of the valve 243a. A gas supply pipe 232e is connected to the gas supply pipe 232b on the downstream side of the valve 243b. A gas supply pipe 232f is connected to the gas supply pipe 232c on the downstream side of the valve 243c. At the gas supply pipes 232d to 232f, MFCs 241d to 241f and valves 243d to 243f are respectively installed sequentially from the upstream side of a gas flow. The gas supply pipes 232a to 232f are made of, for example, a metallic material such as stainless steel or the like.

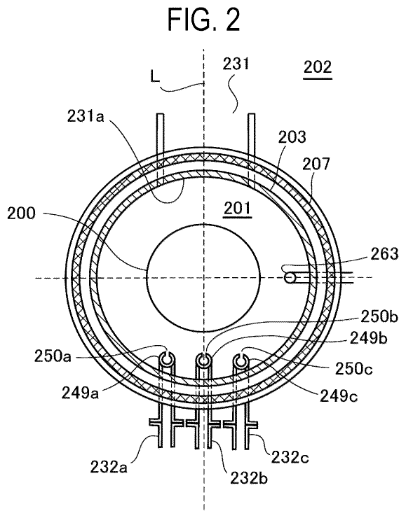

As shown in FIG. 2, each of the nozzles 249a to 249c is installed in an annular space (in a plane view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In the plane view, the nozzle 249b is disposed so as to face an exhaust port 231a which is described below on a straight line with centers of the wafers 200 loaded into the process chamber 201, which are interposed therebetween. The nozzles 249a and 249c are arranged so as to sandwich a straight line L passing through the nozzle 249b and the center of the exhaust port 231a from both sides along the inner wall of the reaction tube 203 (the outer peripheries of the wafers 200). The straight line L is also a straight line passing through the nozzle 249b and the centers of the wafers 200. That is, it may be said that the nozzle 249c is installed on the side opposite to the nozzle 249a with the straight line L interposed therebetween. The nozzles 249a and 249c are arranged in line symmetry with the straight line L as the axis of symmetry. Gas supply holes 250a to 250c configured to supply a gas are formed on the side surfaces of the nozzles 249a to 249c, respectively. Each of the gas supply holes 250a to 250c is opened so as to oppose (face) the exhaust port 231a in the plane view, which enables a gas to be supplied toward the wafers 200. A plurality of gas supply holes 250a to 250c are formed from the lower side to the upper side of the reaction tube 203.

A modifying agent is supplied from the gas supply pipe 232a into the process chamber 201 via the MFC 241a, the valve 243a, and the nozzle 249a.

A first reactant as a reactant is supplied from the gas supply pipe 232b into the process chamber 201 via the MFC 241b, the valve 243b, and the nozzle 249b.

A second reactant as a reactant and a remover are supplied from the gas supply pipe 232c into the process chamber 201 via the MFC 241c, the valve 243c, and the nozzle 249c.

An inert gas is supplied from the gas supply pipes 232d to 232f into the process chamber 201 via the MFCs 241d to 241f, the valves 243d to 243f, the gas supply pipes 232a to 232c, and the nozzles 249a to 249c, respectively. The inert gases act as a purge gas, a carrier gas, a dilution gas, and the like.

A modifying agent supply system (modifying agent exposure system) mainly includes the gas supply pipe 232a, the MFC 241a, and the valve 243a. A first reactant supply system (a first reactant exposure system) mainly includes the gas supply pipe 232b, the MFC 241b, and the valve 243b. A second reactant supply system (a second reactant exposure system) and a remover supply system (a remover exposure system) mainly include the gas supply pipe 232c, the MFC 241c, and the valve 243c. An inert gas supply system mainly includes the gas supply pipes 232d to 232f, the MFCs 241d to 241f, and the valves 243d to 243f. Each or both of the first reactant supply system and the second reactant supply system are also referred to as a reactant supply system (a reactant exposure system). The remover supply system can also supply a remover excited into a plasma state, and also functions as an energy applier configured to apply plasma energy as energy to a substrate. Further, the remover supply system can supply a heated remover, and also functions as an energy applier configured to apply thermal energy as energy to a substrate. Further, the remover supply system also functions as an energy applier configured to apply kinetic energy as energy to a substrate by supplying a remover.

One or the entirety of the various supply systems described above may be constituted as an integrated supply system 248 in which the valves 243a to 243f, the MFCs 241a to 241f and the like are integrated. The integrated supply system 248 is connected to each of the gas supply pipes 232a to 232f, and is configured such that operations of supplying various substances (various gases) into the gas supply pipes 232a to 232f, i.e., opening/closing operations of the valves 243a to 243f, flow rate regulating operations by the MFCs 241a to 241f, and the like are controlled by a controller 121, which is be described below. The integrated supply system 248 is constituted as an integral-type or detachable-type integrated unit, and may be attached to or detached from the gas supply pipes 232a to 232f, and the like on an integrated unit basis, such that maintenance, replacement, expansion, and the like of the integrated supply system 248 can be performed on an integrated unit basis.

The exhaust port 231a configured to exhaust an internal atmosphere of the process chamber 201 is installed below the sidewall of the reaction tube 203. As shown in FIG. 2, in the plane view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a. A vacuum pump 246 as a vacuum exhauster, is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure regulation part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. The seal cap 219 is made of, for example, a metal material such as SUS, and is formed in a disc shape. An O-ring 220b, which is a seal making contact with the lower end of the manifold 209, is installed on an upper surface of the seal cap 219. A rotator 267 configured to rotate a boat 217, which is described below, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transfer apparatus (transfer mechanism) configured to loads or unload (transfer) the wafers 200 into or out of the process chamber 201 by moving the seal cap 219 up or down.

A shutter 219s, which serves as a furnace opening lid configured to be capable of hermetically sealing a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed in multiple stages at a lower side of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

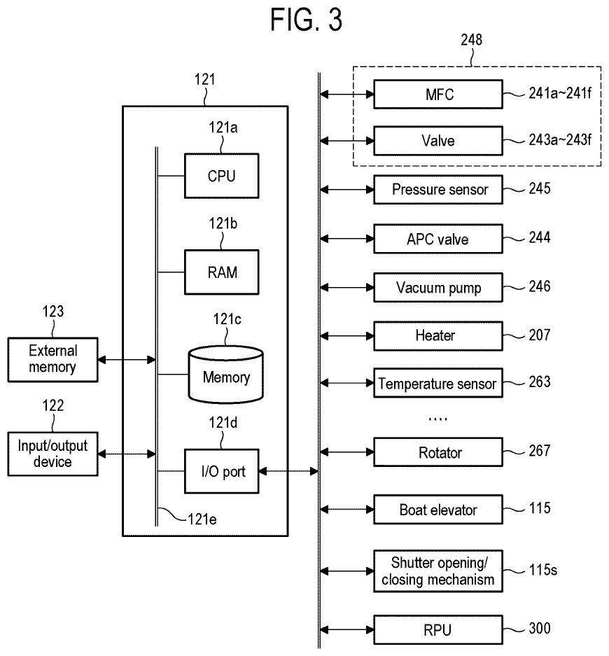

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted as, e.g., a touch panel or the like, is connected to the controller 121. Further, an external memory 123 may be connected to the controller 121. Further, the processing apparatus may be configured to include one controller, or may be configured to include a plurality of controllers. That is, control to perform a processing sequence which is described below may be performed by using one controller, or may be performed by using a plurality of controllers. Further, the plurality of controllers may be constituted as a control system in which the plurality of controllers are connected to each other via a wired or wireless communication network, and the entire control system may perform control to perform the processing sequence which is described below. When the term “controller” is used in the present disclosure, it may include a plurality of controllers or a control system constituted by a plurality of controllers, as well as one controller.

The memory 121c is constituted by, for example, a flash memory, a hard disk drive (HDD), a solid state drive (SSD), or the like. A control program to control operations of a processing apparatus, a process recipe in which sequences and conditions of a substrate processing process which is described below are written, etc. are readably recorded and stored in the memory 121c. The process recipe functions as a program that is combined to cause, by the controller 121, the processing apparatus to execute each sequence in a substrate processing process (an etching process, etc.), which is described below, to obtain an expected result. Hereinafter, the process recipe and the control program may be generally and simply referred to as a “program (program product).” Further, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling the flow rate regulating operation of various kinds of materials (gases) by the MFCs 241a to 241f, the opening/closing operation of the valves 243a to 243f, the opening/closing operation of the APC valve 244, the pressure regulating operation performed by the APC valve 244 based on the pressure sensor 245, the actuating and stopping operation of the vacuum pump 246, the temperature regulating operation performed by the heater 207 based on the temperature sensor 263, the operation of rotating the boat 217 and adjusting the rotation speed of the boat 217 with the rotator 267, the operation of moving the boat 217 up or down by the boat elevator 115, the opening/closing operation of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using communication means or unit such as the Internet or a dedicated line, instead of using the external memory 123.

### (2) Processing Process

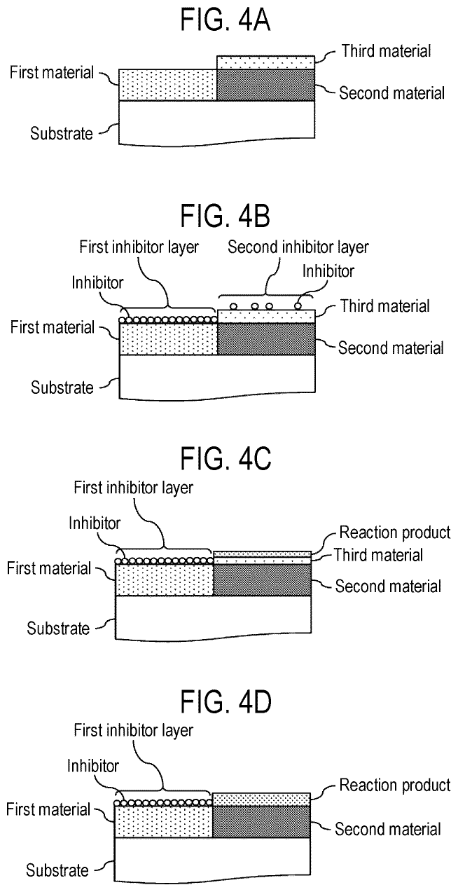

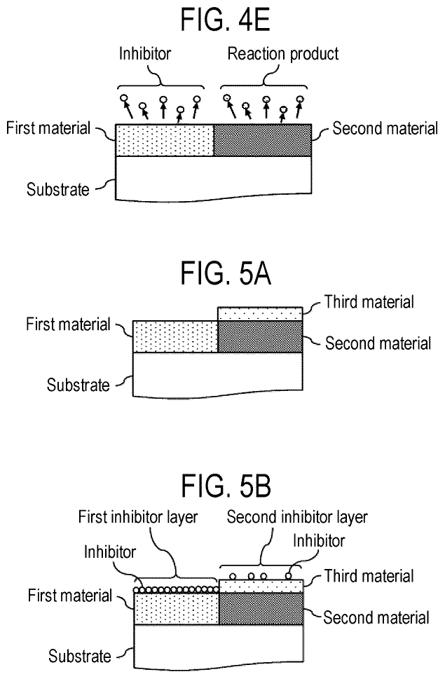

A method of processing a substrate (processing method) as a process (a method) of manufacturing a semiconductor device by using the above-described processing apparatus, i.e., an example of a processing sequence to selectively remove a third material among a first material, a second material, and the third material on a surface of a wafer 200 as a substrate, will be described mainly with reference to FIGS. 4A to 4E. In the following description, operations of the respective components constituting the processing apparatus are controlled by the controller 121.

The processing apparatus is also referred to as a substrate processing apparatus, an etching processing apparatus, or an etching apparatus. The processing method is also referred to as a substrate processing method, an etching processing method, or an etching method. Each or the entirety of the components of the processing apparatus used in performing steps A and B to be described below are also referred to as a provider configured to provide a substrate. The respective components of the processing apparatus used in performing step C to be described below, i.e., one or the entirety of the heater 207 and the remover supply system described above, are also referred to as an energy appliers configured to apply energy to a substrate.

A processing sequence according to the embodiments of the present disclosure includes removing a third material by performing a cycle a predetermined number of times (n times where n is an integer of 1 or 2 or more), the cycle including: a step of providing a wafer 200 subjected to processes including (a) step A of exposing the wafer 200 including a first material and the third material formed on a second material on a surface of the wafer 200 to a modifying agent to allow an inhibitor contained in the modifying agent to be adsorbed on a surface of the first material and (b) step B of exposing the wafer 200 to a reactant to allow at least a portion of the third material to react with the reactant to generate a reaction product; and (c) step C of applying energy to the wafer 200 to perform removal of the reaction product and at least one selected from the group of removal and deactivation of the inhibitor in parallel. This series of processes is also called etching processing.

In the following example, a case where a cycle including steps A to C is performed once will be described.

In addition, in the processing sequence according to the embodiments of the present disclosure, there will be described a case where the reactant used in step B includes a first reactant and a second reactant that reacts with the first reactant, and step B includes at least one selected from the group of alternately exposing the wafer 200 to the first reactant and the second reactant and simultaneously exposing the wafer 200 to the first reactant and the second reactant.

In the following example, there will be described a case where in step B, a cycle including step B1 of exposing the wafer 200 to the first reactant and step B2 of exposing the wafer 200 to the second reactant is performed a predetermined number of times (m times where m is an integer of 1 or 2 or more), i.e., a case where the wafer 200 is alternately exposed to the first reactant and the second reactant.

In the present disclosure, the above-mentioned processing sequence may be denoted as follows for the sake of convenience. In the following, “P” indicates a process of purging a space in which the wafer 200 exists, i.e., an inside of the process chamber 201. Further, “parallel removal” indicates a process performed in step C, i.e., a process of simultaneously performing removal of a reaction product generated on the surface of the wafer 200 in step B, and at least one selected from the group of removal and deactivation of an inhibitor adsorbed on the surface of the wafer 200 in step A in parallel. In the present disclosure, this parallel process performed in step C is also referred to as “parallel removal.” In the following description of a modification, the same notation may be used. In the present disclosure, deactivation of an inhibitor means deactivation of an action of the inhibitor, i.e., an inhibitor effect, which is described below.

$$[ modifying agent \to P \to ( first reactant \to second reactant ) \times m \to parallel removal ] \times n$$

The term “wafer” used in the present disclosure may refer to a wafer itself or a stacked body of a wafer and a predetermined layer or film (substance) formed on a surface of the wafer. When the phrase “a surface of a wafer” is used herein, it may refer to a surface of a wafer itself or a surface of a predetermined layer or the like formed on a wafer. When the expression “a predetermined layer is formed on a surface of a wafer” is used herein, it may mean that a predetermined layer is directly formed on a surface of a wafer itself or that a predetermined layer is formed on a layer or the like formed on a wafer. Furthermore, in the present disclosure, when the phrase “applying energy to a wafer” is used, it may mean applying energy to the wafer itself, or may mean applying energy to a reaction product generated on the surface of the wafer or an inhibitor adsorbed on the surface of the wafer. The term “substrate” used in the present disclosure may be synonymous with the term “wafer.”

As used herein, terms such as “agent,” and “substance” include at least one selected from the group of a gaseous substance and a liquid substance. The liquid substance includes misty substance. That is, each of the modifying agent, the reactant (the first reactant and the second reactant), and the remover may include a gaseous substance, a liquid substance such as a misty substance, or both.

### (Wafer Charging and Boat Loading)

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted up by the boat elevator 115 to be loaded into the process chamber 201 (boat loading). In this state, the seal cap 219 seals the lower end of the manifold 209 via the O-ring 220b. Thus, the wafers 200 are provided inside the process chamber 201.

As shown in FIG. 4A, the wafer 200 charged to the boat 217 includes a first material and a third material formed on a second material on the surface of the wafer 200. The first material, the second material, and the third material are also referred to as a first base, a second base, and a third base, respectively. The surfaces of the first material, the second material, and the third material are also referred to as a first surface, a second surface, and a third surface, respectively.

The third material may contain an element which is the same as an element constituting the first material. Both of the first material and the third material may contain the same plurality of elements, the first material may have a first composition, and the third material may have a second composition different from the first composition. In addition, both of the first material and the third material may contain the same plurality of elements, the first composition may include a stoichiometric composition, and the second composition may include a non-stoichiometric composition.

A density of the third material may be lower than a density of the first material. When both the first material and the third material contain a first element and a second element, an atomic concentration of the second element contained in the third material may be lower than an atomic concentration of the second element contained in the first material.

In addition, a density of adsorption sites on the surface of the third material may be lower than a density of adsorption sites on the surface of the first material. That is, a density of hydroxyl group terminations (OH terminations) on the surface of the third material may be lower than a density of OH terminations on the surface of the first material.

The first material may include at least one selected from the group of a thermal oxide film and a deposited oxide film, and the third material may include at least one selected from the group of a native oxide film and a chemical oxide film. As used herein, the term “thermal oxide film” refers to an oxide film formed by a thermal oxidation method. The term “deposited oxide film” refers to an oxide film formed (deposited) by a method such as a chemical vapor deposition (CVD) method. The term “native oxide film” refers to an oxide film formed on the surface of the wafer 200 by leaving the wafer 200 in the atmosphere. The term “chemical oxide film” refers to an oxide film formed on the surface of the wafer 200 by performing a predetermined cleaning process (SC-1, SC-2, etc.) by using a cleaning liquid on the wafer 200.

The element constituting the second material and the composition of the second material are not particularly limited. The second material may contain an element which is the same as the element constituting the first material or the third material, or may contain an element different from the element constituting the first material or the third material. In addition, the second material may have the composition which is the same as the composition of the first material or the third material, or may have the composition which is different from the composition of the first material or the third material.

Hereinafter, a case where the first material is a thermal oxide film, the second material is a nitride film, and the third material is a native oxide film will be described as an example. Specifically, in this example, each of the first material and the third material contains silicon (Si) as a first element and oxygen (O) as a second element. The first material includes a silicon oxide film (SiO₂ film) of a first composition (Si:O=1:2), and the third material includes a silicon oxide film (SiOₓ film) of a second composition (Si:O=1:x) different from the first composition. In this regard, the first composition is a stoichiometric composition, the second composition is a non-stoichiometric composition, and x in SiOₓ is a real number less than 2. In addition, the density of the third material is lower than the density of the first material, the concentration of O contained in the third material is lower than the concentration of O contained in the first material, and the density of adsorption sites (OH terminations) on the surface of the third material is lower than the density of adsorption sites (OH terminations) on the surface of the first material. Further, in this example, the second material includes a silicon nitride film (SiN film) containing Si as a first element and nitrogen (N) as a third element and containing a third composition (Si:N=3:4). That is, in this example, constituent elements, composition, and material of the second material are different from those of the first material and the third material.

### (Pressure Regulation and Temperature Adjustment)

After the boat loading is completed, the inside of the process chamber 201 is vacuum-exhausted (decomposition-exhausted) by the vacuum pump 246 to reach a desired pressure (degree of vacuum). In this operation, an internal pressure of the process chamber 201 is measured by the pressure sensor 245, and the APC valve 244 is feedback-controlled based on the measured pressure information. Further, the wafer 200 in the process chamber 201 is heated by the heater 207 to reach a desired processing temperature. At this time, a state of supplying electric power to the heater 207 is feedback-controlled based on the temperature information detected by the temperature sensor 263 such that a temperature distribution in the process chamber 201 becomes a desired temperature distribution. Further, the rotation of the wafer 200 by the rotator 267 is started. The exhaust of the inside of the process chamber 201 and the heating and rotation of the wafer 200 are continuously performed at least until the processing on the wafer 200 is completed.

### (Step A)

Then, the wafer 200 is exposed to a modifying agent.

Specifically, the valve 243a is opened to allow a modifying agent to flow through the gas supply pipe 232a. A flow rate of the modifying agent is regulated by the MFC 241a. The modifying agent is supplied into the process chamber 201 via the nozzle 249a, and exhausted via the exhaust port 231a. At this time, the modifying agent is supplied to the wafer 200 from a lateral side of the wafer 200, and the wafer 200 is exposed to the modifying agent (modifying agent supply and exposure). At this time, the valves 243d to 243f may be opened to supply an inert gas into the process chamber 201 via each of the nozzles 249a to 249c.

By exposing the wafer 200 to the modifying agent under processing conditions, which are described below, as shown in FIG. 4B, the inhibitor contained in the modifying agent can be adsorbed on the surface of the first material, and a first inhibitor layer can be selectively formed on the surface of the first material out of the first material and the third material. The inhibitor contains at least a portion of the molecular structure of the molecule constituting the modifying agent, i.e., a residue contained in the modifying agent and derived from the modifying agent.

The first inhibitor layer is an aggregate of inhibitors and includes a high-density layer that densely covers the surface of the first material. The first inhibitor layer may include a layer that continuously covers the surface of the first material, i.e., a continuous layer. The first inhibitor layer prevents the reactant from contacting with the surface of the first material in step B, which is described below, and functions to suppress or inhibit (prevent) the progress of the reaction between the first material and the reactant. That is, the first inhibitor layer functions as a protective layer that protects the first material in step B which is described below. The above-mentioned effect of the first inhibitor layer is also called an inhibitor effect (a reaction suppression effect or a reaction inhibition effect). Further, the first inhibitor layer may not be a continuous layer and may be a discontinuous layer as long as it has the inhibitor effect. Even in a case where the first inhibitor layer is a discontinuous layer, the inhibitor effect can be obtained by forming gaps in discontinuous portions of the discontinuous layer with such a size that the molecules of the reactant cannot pass through the gaps.

In the present disclosure, for example, the expression “selectively forming a layer on the surface of the first material out of the first material and the third material” means a relative relationship of a degree of layer formation on each surface. That is, this expression means that a layer is formed so that the degree of layer formation on the surface of the first material is higher than the degree of layer formation on the surface of the third material. That is, the expression “selectively” in the present disclosure means that processing of one material is performed preferentially over processing of the other material. The same applies to the description of the processing in step B which is described below.

That is, in step A, the above-described inhibitor may be adsorbed on the surface of the first material and the surface of the third material, and a second inhibitor layer may be formed on the surface of the third material. FIG. 4B shows a case where the second inhibitor layer is formed on the surface of the third material. In this case, the density of the inhibitor adsorbed on the surface of the third material is lower than the density of the inhibitor adsorbed on the surface of the first material. That is, the density of the second inhibitor layer is lower than the density of the first inhibitor layer. Further, the thickness of the second inhibitor layer may be smaller than the thickness of the first inhibitor layer. The second inhibitor layer is an aggregate of inhibitors, and includes a low-density layer that discontinuously (sparsely) covers the surface of the third material, i.e., a discontinuous layer. The gaps in the discontinuous portions of the discontinuous layer constituting the second inhibitor layer are large enough for the molecules of the reactant to pass through the gaps, and the surface of the third material is partially exposed, allowing the reactant to come into contact with the surface of the third material in step B, which is described below. Then, the reaction between the third material and the reactant proceeds from the contact point. That is, the second inhibitor layer is low in its inhibitor effect and does not substantially function as a protective layer to protect the third material in step B, which is described below.

After forming the first inhibitor layer on the surface of the first material and forming the second inhibitor layer on the surface of the third material, the valve 243a is closed to stop the supply of the modifying agent into the process chamber 201. Then, the inside of the process chamber 201 is vacuum-exhausted to remove gaseous substances remaining in the process chamber 201 from the inside of the process chamber 201. At this time, the valves 243d to 243f are opened to supply an inert gas into the process chamber 201 via the nozzles 249a to 249c. The inert gas supplied from the nozzles 249a to 249c acts as a purge gas, thereby purging the inside of the process chamber 201 (purging). The processing temperature when purging in this step may be the same as the processing temperature when supplying the modifying agent.

Processing conditions when the modifying agent is supplied in step A are exemplified as follows.
Processing temperature: room temperature (25 degrees C.) to 500 degrees C., preferably room temperature to 250 degrees C.
Processing pressure: 1 to 2,000 Pa, specifically 10 to 1,000 Pa
Processing time: 1 to 3,600 seconds, specifically 5 to 300 seconds
Supply flow rate of modifying agent: 0.001 to 10 slm, specifically 0.1 to 0.5 slm
Supply flow rate of inert gas (per gas supply pipe): 0 to 20 slm.

In the present disclosure, notation of a numerical range such as “25 to 500 degrees C.” means that a lower limit value and an upper limit value are included in the range. Therefore, for example, “25 to 500 degrees C.” means “25 degrees C. or higher and 500 degrees C. or lower.” The same applies to other numerical ranges. In the present disclosure, a processing temperature means a temperature of the wafer 200 or an internal temperature of the process chamber 201, and a processing pressure means an internal pressure of the process chamber 201. Further, the processing time means a time during which a process is continued. Further, when 0 slm (sccm) is included in a supply flow rate, it means a case where no substance (gas) is supplied. The same applies to the following description.

As the modifying agent, for example, a substance containing at least one selected from the group of a hydrocarbon group such as an alkyl group or the like and an amino group may be used.

For example, the modifying agent may be bis(dipropylamino)dimethylsilane ([(C₃H₇)₂N]₂Si(CH₃)₂), bis(dipropylamino)diethylsilane ([(C₃H₇)₂N]₂Si(C₂H₅)₂), bis(dimethylamino)dimethylsilane ([(CH₃)₂N]₂Si(CH₃)₂), bis(diethylamino)diethylsilane ([(C₂H₅)₂N]₂Si(C₂H₅)₂), bis(dimethylamino)diethylsilane ([(CH₃)₂N]₂Si(C₂H₅)₂), bis(diethylamino)dimethylsilane ([(C₂H₅)₂N]₂Si(CH₃)₂), bis(dimethylamino)silane ([(CH₃)₂N]₂SiH₂), bis(diethylamino)silane ([(C₂H₅)₂N]₂SiH₂), bis(dimethylaminodimethylsilyl)ethane ([(CH₃)₂N(CH₃)₂Si]₂C₂H₆), bis(dipropylamino)silane ([(C₃H₇)₂N]₂SiH₂), bis(dibutylamino)silane ([(C₄H₉)₂N]₂SiH₂), (dimethylsilyl)diamine ((CH₃)₂Si(NH₂)₂), (diethylsilyl)diamine ((C₂H₅)₂Si(NH₂)₂), (dipropylsilyl)diamine ((C₃H₇)₂Si(NH₂)₂), bis(dimethylaminodimethylsilyl) methane ([(CH₃)₂N(CH₃)₂Si]₂CH₂), bis(dimethylamino)tetramethyldisilane ([(CH₃)₂N]₂ (CH₃)₄Si₂), (dipropylamino)trimethylsilane ((C₃H₇)₂NSi(CH₃)₃), (dibutylamino)trimethylsilane ((C₄H₉)₂NSi(CH₃)₃), (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃), and the like. One or more of these substances may be used as the modifying agent. In addition to such organic substances, inorganic substances may also be used as the modifying agent.

As the inert gas, a nitrogen (N₂) gas, or a rare gas such as an argon (Ar) gas, a helium (He) gas, a neon (Ne) gas or a xenon (Xe) gas may be used. One or more of these gases may be used as the inert gas. The same applies to each step described below.

### (Step B)

After step A is completed, the following steps B1 and B2 are performed to alternately expose the wafer 200 to a first reactant and a second reactant. In the embodiments, steps B1 and B2 are performed continuously without purging the process chamber 201 between them.

### (Step B1)

In step B1, the wafer 200 is exposed to a first reactant.

Specifically, the valve 243b is opened to allow the first reactant to flow through the gas supply pipe 232b. A flow rate of the first reactant is regulated by the MFC 241b. The first reactant is supplied into the process chamber 201 via the nozzle 249b and exhausted via the exhaust port 231a. At this time, the first reactant is supplied to the wafer 200 from the lateral side of the wafer 200, and the wafer 200 is exposed to the first reactant (first reactant supply and exposure). At this time, the valves 243d to 243f may be opened to supply an inert gas into the process chamber 201 via each of the nozzles 249a to 249c.

By exposing the wafer 200 to the first reactant under processing conditions described below, the first reactant can be adsorbed on the surface of the third material, i.e., the surface of the third material that is not covered with the second inhibitor. In addition, the inside of the process chamber 201 can be made into an atmosphere of the first reactant.

After the first reactant is adsorbed on the surface of the third material and the inside of the process chamber 201 is made into an atmosphere of the first reactant, the valve 243b is closed to stop the supply of the first reactant into the process chamber 201.

### (Step B2)

In step B2, the wafer 200 is exposed to a second reactant.

Specifically, the valve 243c is opened to allow the second reactant to flow through the gas supply pipe 232c. A flow rate of the second reactant is regulated by the MFC 241c. The second reactant is supplied into the process chamber 201 via the nozzle 249c and exhausted via the exhaust port 231a. At this time, the second reactant is supplied to the wafer 200 from the lateral side of the wafer 200, and the wafer 200 is exposed to the second reactant (second reactant supply and exposure). At this time, the valves 243d to 243f may be opened to supply an inert gas into the process chamber 201 via each of the nozzles 249a to 249c.

By exposing the wafer 200 to the second reactant under processing conditions described below, it is possible to cause the surface of the third material to react with the first reactant adsorbed on the surface of the third material and the second reactant. It is also possible to cause the surface of the third material to react with the first reactant and the second reactant floating in the process chamber 201. These reactions alter the surface of the third material. As shown in

FIG. 4C, these reactions make it possible to generate a solid reaction product such as ammonium silicofluoride, i.e., ammonium hexafluorosilicate ((NH₄)₂SiF₆), on the surface of the third material.

After the surface of the third material is altered to generate a reaction product, the valve 243c is closed to stop the supply of the second reactant into the process chamber 201.

### (Performing a Predetermined Number of Times)

By performing a cycle including the above-mentioned steps B1 and B2 a predetermined number of times (m times where m is an integer of 1 or 2 or more), it is possible to modify at least a portion of the third material and change (convert) the same into a layer containing a reaction product. The above-described cycle may be performed a plurality of times. That is, a thickness of the third material to be modified per cycle may be made to be smaller than a desired modification thickness (a predetermined thickness or a predetermined depth) of the third material, and the above-described cycle may be performed a plurality of times until the modification thickness of the third material reaches the desired modification thickness (the predetermined thickness or the predetermined depth). By performing the above-mentioned cycle a predetermined number of times, it is also possible to modify the entire third material and change (convert) the entire third material into a layer containing a reaction product, as shown in FIG. 4D.

In this step, it is possible to selectively alter at least a portion of the third material while suppressing the alteration of the first material. In this step, the selective alteration of the third material is possible because, as described above, a high-density first inhibitor layer functions as a protective layer for the first material, while a low-density second inhibitor layer does not substantially function as a protective layer for the third material. The alteration of the third material progresses, for example, with the gaps between the inhibitors contained in the second inhibitor layer as starting points, and extends to the entire surface of the third material. To advance this selective alteration, step B may be performed under conditions in which at least one selected from the group of removal and deactivation of the first inhibitor layer is suppressed. The low-density second inhibitor layer may be removed from the surface of the third material or deactivated during the process of alteration of the underlying third material. FIG. 4D shows a case in which the second inhibitor layer is removed from the surface of the third material during the process of alteration of the third material. In this step, the second inhibitor layer may be left on the surface of the third material without being removed.

Processing conditions when the first reactant is supplied in step B1 are exemplified as follows.
Processing temperature: room temperature to 90 degrees C., specifically 45 to 80 degrees C., more specifically 50 to 70 degrees C.
Processing pressure: 10 to 2,000 Pa, specifically, 50 to 1,000 Pa
Processing time: 60 to 180 seconds, specifically, 60 to 120 seconds
Supply flow rate of first reactant: 0.5 to 3 slm, specifically 1 to 2 slm
Supply flow rate of inert gas (per gas supply pipe): 0.5 to 10 slm, specifically 1 to 5 slm.

Processing conditions when the second reactant is supplied in step B2 are exemplified as follows.
Processing temperature: room temperature to 90 degrees C., specifically 45 to 80 degrees C., more specifically 50 to 70 degrees C.
Processing pressure: 10 to 2,000 Pa, specifically 50 to 1,000 Pa
Processing time: 60 to 180 seconds, specifically 60 to 120 seconds
Supply flow rate of second reactant: 0.1 to 3 slm, specifically 0.2 to 2 slm
Supply flow rate of inert gas (per gas supply pipe): 0.5 to 10 slm, preferably 1 to 5 slm

As the first reactant, a fluorine (F)-containing substance as a halogen-containing substance may be used. As the F-containing substance, for example, chlorine (Cl)- and F-containing substances, N- and F-containing substances, or hydrogen (H)- and F-containing substances, such as chlorine trifluoride (ClF₃), chlorine fluoride (ClF), nitrogen trifluoride (NF₃), hydrogen fluoride (HF), and fluorine (F₂), may be used. That is, as the first reactant, for example, an interhalogen compound, a nitrogen halide, a hydrogen halide, and a halogen element may be used. In addition, as the first reactant, an aqueous solution including a F-containing substance, for example, an aqueous HF solution may be used without being limited to a gaseous substance. As the first reactant, one or more of these substances may be used.

A reducing agent may be used as the second reactant. Examples of the reducing agent include H-containing substances, N- and H-containing substances, C-, N- and H-containing substances, such as hydrogen (H₂), ammonia (NH₃), diazene (N₂H₂), hydrazine (N₂H₄), N₃H₈, monomethylamine ((CH₃)NH₂), dimethylamine ((CH₃)₂NH), trimethylamine ((CH₃)₃N), monoethylamine ((C₂H₅)NH₂), diethylamine ((C₂H₅)₂NH), triethylamine ((C₂H₅)₃N), monomethylhydrazine ((CH₃)HN₂H₂), dimethylhydrazine ((CH₃)₂N₂H₂), trimethylhydrazine ((CH₃)₂N₂ (CH₃) H), and the like. That is, examples of the second reactant include hydrogen, hydrogen nitride, amine, and organic hydrazine. One or more of these substances may be used as the second reactant.

### (Step C)

After step B is completed, energy is applied to the wafer 200 in predetermined procedures to perform, in parallel, removal of the reaction product generated on the surface of the wafer 200 and at least one selected from the group of removal and deactivation of the inhibitor remaining on the surface of the wafer 200 (parallel removal). These procedures may combined arbitrarily.

For example, in this step, the parallel removal may be performed by exposing the wafer 200 to a remover that reacts with at least one selected from the group of the inhibitor and the reaction product, and applying energy to the wafer 200. The remover may be supplied to the wafer 200 from a remover supply system in the same procedure as in step B2. The remover is supplied from the gas supply pipe 232c via the nozzle 249c into the process chamber 201 and exhausted via the exhaust port 231a. At this time, the remover is supplied to the wafer 200 from the lateral side of the wafer 200, and the wafer 200 is exposed to the remover (remover supply and exposure). By exposing the wafer 200 to the remover that reacts with at least one selected from the group of the inhibitor and the reaction product, and applying energy to the wafer 200, it is possible to perform the parallel removal while generating at least one selected from the group of a chemical reaction between the remover and the inhibitor and a chemical reaction between the remover and the reaction product. As a result, it is possible to perform the parallel removal more efficiently and effectively.

In addition, for example, in this step, the parallel removal may be performed by applying thermal energy to the wafer 200. In this case, in this step, the wafer 200 may be heated by the heater 207 to a temperature equal to or higher than the temperature of the wafer 200 in step B or to a temperature higher than the temperature of the wafer 200 in step B (thermal energy supply). Further, in this step, the wafer 200 may be heated to the above-mentioned temperature by exposing the wafer 200 to the remover heated by the heater 207. In this case, the supply of the remover to the wafer 200 may be performed in the same manner as the above-mentioned remover supply and exposure.

In addition, for example, in this step, the parallel removal may be performed by applying plasma energy to the wafer 200. For example, in this step, the above-mentioned remover may be excited (activated) into a plasma state and supplied to the wafer 200 (plasma energy supply). In this case, in this step, the temperature of the wafer 200 may be set to a temperature equal to or lower than room temperature. As described above, the remover supply system may also supply a remover excited into a plasma state. In this case, the supply of the remover to the wafer 200 may be performed in the same manner as the above-mentioned remover supply and exposure.

By applying energy to the wafer 200 under the processing conditions which are described below, as shown in FIG. 4E, it becomes possible to perform, in parallel, removal (sublimation) of the reaction product generated in step B, and at least one selected from the group of removal and deactivation of the inhibitor adsorbed on the surface of the first material by performing step A and remained on the surface of the first material after performing step B (parallel removal). FIG. 4E shows a case where the inhibitor adsorbed and remained on the surface of the first material is removed through parallel removal.

By removing the reaction product and the inhibitor, the surface of the first material and the surface of the second material are exposed. By removing the inhibitor from the surface of the first material, when a film is subsequently formed on the surface of the first material, it is possible to improve a wafer in-plane film thickness uniformity of the film, interface characteristics between the film and the first material, and a surface roughness. By removing the reaction product from the surface of the second material, when a film is subsequently formed on the surface of the second material, it is possible to improve a wafer in-plane film thickness uniformity of the film, interface characteristics between the film and the second material, and a surface roughness. The term “surface roughness” means a height difference of a film surface in a wafer plane or in any target plane, which indicates that the smaller a value the height difference is, the smoother the surface is. In the present disclosure, the expression “improving the surface roughness” means that the height difference of the film surface is reduced and the smoothness is improved. In addition, in a case where a remover that reacts with at least one selected from the group of the inhibitor and the reaction product is used in the parallel removal, it is possible to utilize the above-mentioned chemical action, bring the surface of each material into a more appropriate state, and further enhance the above-mentioned effects.

In FIG. 4E, there is shown the case where the inhibitor adsorbed on the surface of the first material is removed when performing the parallel removal. However, the embodiments are not limited thereto. For example, when performing the parallel removal, the inhibitor adsorbed on the surface of the first material may be deactivated without being removed. In addition, for example, when performing the parallel removal, a part of the inhibitors adsorbed on the surface of the first material may be removed and the remaining inhibitors may be deactivated. Even in these cases, the above-mentioned effect of improving surface roughness can be obtained for the film formed on the surface of the first material.

Processing conditions when energy is applied to the wafer 200 in step C are exemplified as follows.
Processing temperature: 100 to 1,000 degrees C., specifically 400 to 700 degrees C.
Processing pressure: 1 to 120,000 Pa, specifically 1 to 4,000 Pa
Processing time: 1 to 18,000 seconds, specifically 1 to 9,000 seconds
Supply flow rate of remover: 0 to 50 slm, specifically 1 to 20 slm
RF power: 0 to 10,000 W, specifically 0 to 5,000 W

The RF power is the power applied to generate plasma when performing plasma processing by using a remover. When the RF power is 0 W, it means a case where plasma energy is not generated. That is, the above-mentioned parallel removal may also be performed by supplying a remover under non-plasma conditions. Moreover, when the supply flow rate of remover is 0 slm, it means a case where a remover is not supplied. That is, the above-mentioned parallel removal can also be performed by, for example, thermal energy generated by heating, without supplying the remover.

As the remover, for example, a reducing agent or an oxidizing agent may be used.

As the reducing agent, for example, N- and H-containing substances, H-containing substances, or deuterium (D)-containing substances, such as NH₃, N₂H₂, N₂H₄, N₃H₈, H₂, and deuterium (D₂) may be used.

Examples of oxidizing agent include oxygen (O)-containing substances, H- and O-containing substances, N- and O-containing substances, and C- and O-containing substances, such as oxygen (O₂), ozone (O₃), water vapor (H₂O), hydrogen peroxide (H₂O₂), nitrous oxide (N₂O), nitric oxide (NO), nitrogen dioxide (NO₂), carbon dioxide (CO₂), carbon monoxide (CO), and the like.

Examples of the remover include mixtures of the reducing agent and the oxidizing agent, such as H₂+O₂, H₂+O₃, D₂+O₂, D₂+O₃, and the like. In the present disclosure, the description of two substances together, such as “H₂+O₂,” means a mixture of H₂ and O₂. When a mixture is supplied, two substances may be mixed (premixed) in a supply pipe and then supplied into the process chamber 201, or two substances may be separately supplied into the process chamber 201 from different supply pipes and mixed (post-mixed) in the process chamber 201.

As the remover, for example, an inert gas such as a He gas, a Ne gas, an Ar gas, a Xe gas, or a N₂ gas may be used. As the remover, a substance that reacts with at least one selected from the group of the inhibitor and the reaction product may be used. However, as described above, a substance that does not react with any one of the inhibitor and the reaction product may also be used.

One or more of these substances may be used as the remover. As described above, these substances may be excited into a plasma state and supplied as the remover, or these substances may be excited by heat and supplied as the remover. In step C, when an O-containing substance is used as the remover, the surface of the wafer 200 (surface of the second material) exposed by the removal of the third material may be oxidized. In this case, the oxide film newly formed on the surface of the wafer 200 is an oxide film with higher uniformity, higher density, and better quality than the third material (native oxide film).

### (After-Purge and Returning to Atmospheric Pressure)

After step C is completed, an inert gas as a purge gas is supplied into the process chamber 201 from each of the nozzles 249a to 249c and is exhausted via the exhaust port 231a. As a result, the inside of the process chamber 201 is purged, and the gases, reaction by-products, and the like remaining in the process chamber 201 are removed from the inside of the process chamber 201 (after-purge). Thereafter, an internal atmosphere of the process chamber 201 is substituted with an inert gas (inert gas substitution), and the internal pressure of the process chamber 201 is returned to a normal pressure (returning to atmospheric pressure).

### (Boat Unloading and Wafer Discharging)

Thereafter, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging).

Steps A to C may be performed in the same process chamber (in-situ). In a case where a series of processes is performed in-situ, the wafer 200 is not exposed to the ambient air during the process, and the wafer 200 can be consistently processed while being placed under vacuum. This makes it possible to perform a stable processing.

### (3) Effects of the Embodiments

According to the embodiments of the present disclosure, one or more of the following effects may be obtained.

When the inhibitor is adsorbed on the surface of the first material on the surface of the substrate and the third material on the second material is selectively etched by using the reactant, the third material may react with the reactant to generate a solid reaction product (such as ammonium silicofluoride). In this case, the reaction product may be removed after stopping the supply of the reactant. In addition, when a film is subsequently formed on the surface of the first material, removal and/or deactivation of the inhibitor present on the surface of the first material is demanded, which may reduce productivity.

As a solution to such a problem, in the embodiments of the present disclosure, the cycle including the above-mentioned steps A to C is performed. Thus, after the inhibitor is adsorbed on the surface of the first material and the reaction product is generated by causing at least a portion of the third material to react with the reactant, it is possible to simultaneously perform removal of the reaction product and removal and/or deactivation of the inhibitor in parallel. As a result, the third material can be selectively removed from among the first material, the second material, and the third material. At that time, it is possible to significantly shorten the processing time while ensuring high selectivity, and to significantly improve the productivity. In addition, the surfaces of the first material and the second material can be cleaned and exposed, and the processing performed on the first material and the second material in the subsequent process can be started appropriately and quickly.

When the removal of the reaction product and the removal and/or deactivation of the inhibitor are performed non-simultaneously, for example, sequentially, one more step is demanded than in the embodiments of the present disclosure, and the productivity is reduced accordingly. Further, in that case, when the removal of the reaction product and the removal and/or deactivation of the inhibitor are performed under different processing conditions, for example, at different processing temperatures, change (increase or decrease) in the processing temperature is demanded, and the productivity is further reduced accordingly. According to the embodiments of the present disclosure, two different processes can be performed simultaneously in parallel under the same processing condition, for example, at the same processing temperature. Therefore, an increase in the number of steps and change (increase or decrease) in the processing temperature is not demanded. As the increase in the number of steps and the change in the processing temperature are not demanded, it possible to significantly increase the productivity.
(b) The reactant includes the first reactant and the second reactant that reacts with the first reactant. In step B, the cycle including steps B1 and B2 is performed a predetermined number of times, thereby making it possible to efficiently and effectively generate the reaction product. Further, step B includes alternately exposing the substrate to the first reactant and the second reactant, thereby making it possible to generate the reaction product with a uniform thickness with good controllability. As a result, it is possible to uniformly remove the third material with good controllability.

In addition, in step B, when the first reactant and the second reactant are alternately supplied, purging of the inside of the process chamber is not performed. Therefore, the first reactant and the second reactant can be mixed in the process chamber. This makes it possible to generate a reaction product at a high rate. As a result, the third material can be removed at a high rate. In addition, supply of the first reactant and supply of the second reactant to the substrate may partially overlap, which makes it possible to generate a reaction product at a higher rate. As a result, the third material can be removed at a higher rate.
(c) The first reactant includes a halogen-containing substance, and the second reactant includes a reducing agent. Therefore, the reaction product can be efficiently and effectively generated in step B, and the above-mentioned action can be effectively generated. Further, the first reactant includes a F-containing substance, and the second reactant includes hydrogen nitride, such that the above-mentioned action can be more effectively generated. In addition, the first reactant contains F and H, and the second reactant contains N and H, such that the above-mentioned action can be more effectively generated.
(d) In step C, by applying at least one selected from the group of thermal energy and plasma energy to the substrate, removal of the reaction product and removal and/or deactivation of the inhibitor can be performed simultaneously in parallel in a more efficient and effective manner, and the above-mentioned action can be more effectively generated. In this case, by heating the substrate in step C to a temperature equal to or higher than the temperature of the substrate in step B or to a temperature higher than the temperature of the substrate in step B, the above-mentioned action can be more effectively generated. Further, in this case, by exposing the substrate in step C to a remover that reacts with at least one selected from the group of the inhibitor and the reaction product, at least one selected from the group of a chemical reaction between the remover and the inhibitor and a chemical reaction between the remover and the reaction product can be generated. That is, in step C, it becomes possible to use (use in combination) the energy applied to the substrate and the chemical action. The removal of the reaction product and the removal and/or deactivation of the inhibitor can be performed simultaneously in parallel in a more efficient and effective manner, and the above-mentioned action can be more effectively generated.
(e) Since the third material contains the same element as the element constituting the first material, it is possible to selectively remove a portion of the material containing the same element on the surface of the substrate while maintaining the other portion of the material without removing the same. For example, when a thermal oxide film (SiO₂) and a native oxide film and/or a chemical oxide film (SiOₓ where 0<x<2), which are oxide films containing Si and O, are exposed on the surface of the substrate, it is possible to selectively remove the native oxide film and/or the chemical oxide film while maintaining the thermal oxide film. This makes it possible to selectively remove a removal target portion, which is a portion of the material containing the same element, with high accuracy, and to significantly improve a processing accuracy of the film.
(f) Both of the first material and the third material contain the same plurality of elements, the first material has a first composition, and the third material has a second composition different from the first composition. Therefore, the inhibitor can be easily adsorbed on the surface of the first material, and the third material can be more easily reacted with the reactant than the first material. This makes it possible to effectively generate selective adsorption of the inhibitor on the surface of the first material and selective reaction of the third material with the reactant.

In this case, the first composition includes a stoichiometric composition, and the second composition includes a non-stoichiometric composition. Therefore, the inhibitor can be more easily adsorbed on the surface of the first material, and the third material can be more easily reacted with the reactant than the first material. This makes it possible to more effectively generate selective adsorption of the inhibitor on the surface of the first material and selective reaction between the third material and the reactant. In addition, when the density of the third material is lower than the density of the first material, the above-mentioned effects can be obtained in the same way.
(g) Both of the first material and the third material contain the first element and the second element, and the atomic concentration of the second element contained in the third material is lower than the atomic concentration of the second element contained in the first material. This makes it easier to adsorb the inhibitor on the surface of the first material and makes the third material more likely to react with the reactant than the first material. Therefore, it is possible to more effectively generate selective adsorption of the inhibitor on the surface of the first material and selective reaction of the third material with the reactant.

The above-described effects can also be obtained when the density of adsorption sites on the surface of the third material is lower than the density of adsorption sites on the surface of the first material, i.e., when the density of OH group terminations on the surface of the third material is lower than the density of OH group terminations on the surface of the first material.
(h) When the first material includes a thermal oxide film or a deposited oxide film, and the third material includes at least one selected from the group of a native oxide film and a chemical oxide film, the above-mentioned effects can be more effectively obtained.
(i) In step A, the inhibitor contained in the modifying agent is adsorbed on the surface of the first material and the surface of the third material. Therefore, when the inhibitor is adsorbed on the surface of the first material, the inhibitor can be allowed to be adsorbed on the surface of the third material, and the density of the inhibitor adsorbed on the surface of the first material can be increased. As a result, the inhibitor effect by the inhibitor adsorbed on the surface of the first material can be enhanced, the selective reaction between the third material and the reactant can be effectively generated, and the selective removal of the third material can be effectively performed.
(j) In step A, by making the density of the inhibitor adsorbed on the surface of the third material lower than the density of the inhibitor adsorbed on the surface of the first material, the inhibitor effect by the inhibitor adsorbed on the surface of the third material can be reduced, and the selective removal of the third material can be more effectively performed.
(k) The above-mentioned effects can be obtained similarly even when a predetermined substance is arbitrarily selected from the various modifying agents, various reactants (first reactant and second reactant), various removers, and various inert gases described above.

### (4) Modifications

The processing sequence according to the embodiments of the present disclosure may be modified as shown in the following modifications. These modifications may be combined arbitrarily. Unless otherwise specified, the processing procedures and processing conditions in each step of each modification may be the same as the processing procedure and processing conditions in each step of the above-described processing sequence.

### First Modification

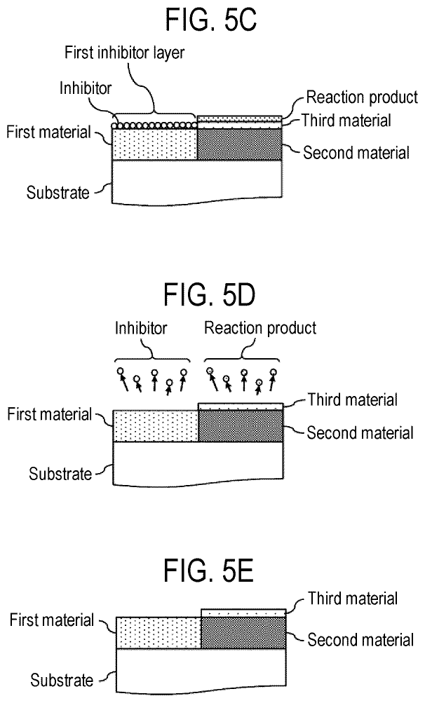

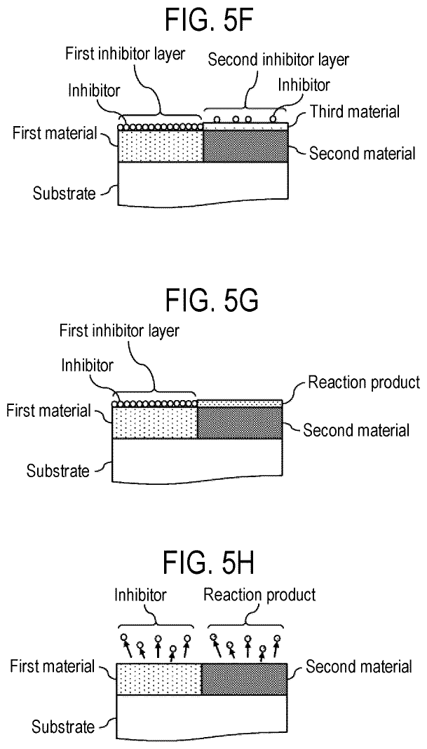

The cycle including steps A to C may be performed a plurality of times. FIGS. 5A to 5H show a case where the third material is selectively removed from among the first material, the second material, and the third material by performing the cycle including steps A to C a plurality of times, for example, twice.

In a first cycle, step A is performed on a substrate with a surface structure shown in FIG. 5A, and as shown in FIG. 5B, an inhibitor is selectively adsorbed on the surface of the first material. Next, step B is performed to change a portion of the third material into a reaction product as shown in FIG. 5C. Next, step C is performed to simultaneously perform removal of the reaction product and removal and/or deactivation of the inhibitor in parallel, as shown in FIG. 5D. FIG. 5D shows a case where the inhibitor is removed from the surface of the first material. Thus, in the first cycle of the modification, a portion of the third material on the surface side is removed.

In a second cycle, step A is performed on the substrate with a surface structure shown in FIG. 5E by way of the first cycle, and the inhibitor is selectively adsorbed on the surface of the first material as shown in FIG. 5F. Next, step B is performed to change the entire remaining portion of the third material into a reaction product as shown in FIG. 5G. Next, step C is performed to simultaneously perform removal of the reaction product and removal and/or deactivation of the inhibitor in parallel, as shown in FIG. 5H. FIG. 5H shows a case where the inhibitor is removed from the surface of the first material. Thus, in the second cycle of this modification, the entire remaining portion of the third material is removed. As a result, the surface of the first material and the surface of the second material are exposed respectively.

As described above, by performing the cycle including steps A to C a plurality of times, the third material can be selectively removed from among the first material, the second material, and the third material, and the same effects as those of the above-described embodiments can be obtained in this modification as well. Further, the cycle including steps A to C may be performed three or more times.

When step B is performed, a portion of the first inhibitor layer may be removed or deactivated, and a portion of the first material may be exposed. Even in this case, according to this modification, the first inhibitor layer is formed again so as to cover the surface of the first material in step A of the next cycle. As a result, in step B performed thereafter, the surface of the first material can be protected by the first inhibitor layer thus formed again, and the etching of the first material can be suppressed. That is, in each step on and after the second cycle, a reaction similar to that in the first cycle can be generated, and the reaction similar to that in the first cycle can be allowed to proceed.

### Second Modification

As in the processing sequences described below, in step B, purging of the inside of the process chamber may be performed when the first reactant and the second reactant are alternately supplied.

$$[ modifying agent \to P \to ( first reactant \to second reactant \to P ) \times m \to parallel removal ] \times n \qquad Modification 2 a$$

$$[ modifying agent \to P \to ( first reactant \to P \to second reactant ) \times m \to parallel removal ] \times n \qquad Modification 2 b$$

$$[ modifying agent \to P \to ( first reactant \to P \to second reactant \to P ) \times m \to parallel removal ] \times n \qquad Modification 2 c$$

In these modifications, the same effects as those of the above-described embodiments can be obtained. In addition, in these modifications, when the first reactant and the second reactant are alternately supplied in step B, the inside of the process chamber is purged at a predetermined timing, such that the altered thickness of the third material in step B can be controlled more precisely. In modifications 2a and 2b, the first reactant and the second reactant can be mixed in the process chamber as in the above-described embodiments, such that the reaction product can be generated at a high rate. As a result, the third material can be removed at a high rate. In addition, supply of the first reactant and supply of the second reactant to the substrate may partially overlap, such that the reaction product can be generated at a relatively high rate. As a result, the third material can be removed at a relatively high rate. In modification 2c, the inside of the process chamber is purged after performing each of steps B1 and B2, and supply of the first reactant and supply of the second reactant to the substrate do not overlap. Therefore, the altered thickness of the third material in step B can be controlled more precisely.

### Third Modification

In a case where the reactant includes a first reactant and a second reactant that reacts with the first reactant, step B may include simultaneously exposing the substrate the first reactant and the second reactant, as in the processing sequences shown below.

$$[ modifying agent \to P \to ( first reactant + second reactant ) \times m \to parallel removal ] \times n \qquad Modification 3 a$$

$$[ modifying agent \to P \to ( first reactant + second reactant \to P ) \times m \to parallel removal ] \times n \qquad Modification 3 b$$

In these modifications, the same effects as in the above-described embodiments can be obtained. Further, in these modifications, by including simultaneously exposing the substrate to the first reactant and the second reactant in step B, the first reactant and the second reactant may be directly mixed in the process chamber, and the reaction product can be generated at a high rate. As a result, the third material can be removed at a high rate.

Further, in these modifications, simultaneous supply of the first reactant and the second reactant is performed intermittently. This makes it possible to improve controllability of an altered thickness of the third material (a thickness of the reaction product to be generated). Further, in modification 3b, the inside of the process chamber is purged when the simultaneous supply of the first reactant and the second reactant is performed intermittently. This makes it possible to more precisely control the altered thickness of the third material in step B.

### Other Embodiments of the Present Disclosure

The embodiments of the present disclosure are specifically described above. However, the present disclosure is not limited to the above-described embodiments, and various modifications may be made without departing from the spirit of the present disclosure.

For example, the first material may include a deposited oxide film, and the third material may include a chemical oxide film. Further, for example, the first material may include a SiOₓ₁ film with a non-stoichiometric composition, and the third material may include SiOₓ₂ film with a non-stoichiometric composition. In this regard, x1 and x2 are real numbers that satisfy a relational expression 2>x1>x2>0. For example, the first material may include a SiO_{1.9} film, and the third material may include a SiO_{1.5} film. Alternatively, the first material may include a SiO_{1.5} film, and the third material may include a SiO_{1.1} film. For example, the first material may include a SiO₂ film (high density) with a stoichiometric composition, and the third material may include a SiO₂ film (low density) with a stoichiometric composition. For example, the first material may include a SiOₓ film (high density) with a non-stoichiometric composition, and the third material may include a SiOₓ film (low density) with a non-stoichiometric composition. In this regard, x is a real number less than 2. In these embodiments, the same effects as in the above-described embodiments can be obtained.

In addition, for example, at least one selected from the group of the first material and the third material may include a silicon oxycarbonate film (SiOC film), a silicon oxynitride film (SiON film), a silicon oxycarbonitride film (SiOCN film), and the like, in addition to the SiO film. For example, the first material may include a SiOC film (high density), and the third material may include a SiOC film (low density). For example, the first material may include a SiOC film (high O concentration), and the third material may include a SiOC film (low O concentration). For example, the first material may include a SiOC film (O-rich), and the third material may include a SiOC film (O-poor). For example, the first material may include a SiOC film (O-rich), and the third material may include a native oxide film. For example, the first material may include a SiON film (O-rich), and the third material may include a native oxide film. For example, the first material may include a SiOCN film (O-rich), and the third material may include a native oxide film. As used herein, the term “O-rich” means a composition in which the atomic concentration of oxygen (O) is excessive as compared with the stoichiometric composition, and the “O-poor” means a composition in which the atomic concentration of oxygen (O) is insufficient as compared with the stoichiometric composition. In either case, the density of the adsorption sites (OH terminations) on the surface of the third material is lower than the density of the adsorption sites (OH terminations) on the surface of the first material. As long as this relationship is satisfied, the first material and the third material may be the same material or different materials. In these embodiments, the same effects as in the above-described embodiments can be obtained.

For example, the second material may include a silicon carbonitride film (SiCN film), a silicon boron carbonitride film (SiBCN film), a silicon boron nitride film (SiBN film), a silicon film (Si film), and the like, in addition to the SiN film. The Si film referred to herein may be any one of an amorphous Si film, a polycrystalline Si film, and an epitaxial Si film. The second material may include monocrystalline Si (Si wafer). The first material may include a SiN film, a SiCN film, a SiBCN film, a SiBN film, a Si film, a monocrystalline Si film, and the like. For example, the first material may include a SiN film, a SiCN film, a SiBCN film, and the like, the second material may include a Si film, a monocrystalline Si film, and the like, and the third material may include a native oxide film, a chemical oxide film, and the like. In these embodiments, the same effects as in the above-described embodiments can be obtained.

Further, for example, the processing procedures, processing conditions, types of remover, and the like used in step C may be appropriately selected depending on the types of various materials, inhibitors, and reaction products present on the surface of the wafer 200.

For example, when a carbon (C)-containing film such as a SiCN film is present on the surface of the wafer 200, step C may be performed under conditions that can suppress the desorption of C from the film. In this regard, in step C, the heat treatment is more desirable than the plasma processing, and the processing using an inert gas or a reducing agent is more desirable than the processing using an oxidizing agent. When the processing using an oxidizing agent is performed, an oxidizing agent with a small oxidizing power may be used.

For example, when the second material (SiN, or the like) serving as a base of the third material (SiOₓ, or the like) is an easily oxidizable material and is not desired to be oxidized, in step C, it is desirable to perform a process using an inert gas or a reducing agent as the remover rather than a process using an oxidizing agent as the remover so as to suppress the oxidation of the second material. When performing the processing using the oxidizing agent as the remover in step C, an oxidizing agent with a small oxidizing power may be used. In addition, in a state in which the surface of the second material is covered with a reaction product, processing using an oxidizing agent as the remover may be performed, and then may be switched to processing using an inert gas or a reducing agent as the remover. That is, in step C, the substance used as the remover may be switched midway, and the parallel removal may be performed in two steps. In this case, by using the oxidizing agent as the remover in the first step, the parallel removal can be performed at a high rate, and by using the inert gas or the reducing agent as the remover in the second step, the parallel removal can be performed while suppressing the oxidation of the second material.

Recipes used in each process may be provided individually according to the processing contents and may be stored in the memory 121c via a telecommunication line or the external memory 123. Moreover, at the beginning of each process, the CPU 121a may properly select an appropriate recipe from the recipes stored in the memory 121c according to the processing contents. Thus, it is possible to perform various processes on material of various kinds, composition ratios, densities, thicknesses, and states with enhanced reproducibility. Further, it is possible to reduce an operator's burden and to quickly start each process while avoiding an operation error.

The recipes mentioned above are not limited to newly-provided ones but may be provided, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which an etching process is performed by using a batch-type processing apparatus configured to process a plurality of substrates at a time is described in the above-described embodiments and modifications. The present disclosure is not limited to the above-described embodiments, but may be applied, for example, to a case where an etching process is performed by using a single-wafer type processing apparatus configured to process a single substrate or several substrates at a time. In addition, an example in which an etching process is performed by using a processing apparatus provided with a hot-wall-type process furnace is described in the above-described embodiments. The present disclosure is not limited to the above-described embodiments, but may be applied to a case where an etching process is performed by using a processing apparatus provided with a cold-wall-type process furnace.

In addition, an example in which the above-described processing sequence is performed in the same process chamber of the same processing apparatus (in-situ) is described in the above-described embodiments. The present disclosure is not limited to the above-described embodiments. For example, any step and any other step of the above-described processing sequence may be performed in different process chambers of different processing apparatuses (ex-situ), or may be performed in different process chambers of the same processing apparatus.

Even in the case of using these processing apparatuses, each process may be performed according to processing procedures and process conditions which are the same as those in the above-described embodiments and modifications, and effects which are the same as those of the above-described embodiments and modifications may be obtained.

The above-described embodiments and modifications may be used in proper combination. Processing procedures and process conditions used in this case may be the same as, for example, the processing procedures and process conditions in the above-described embodiments and modifications.

According to the present disclosure in some embodiments, it is possible to significantly shorten a processing time when selectively removing a specific material on a surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method, comprising:
removing a third material by performing a cycle a predetermined number of times, the cycle including:
providing a substrate subjected to processes including (a) exposing the substrate including a first material and the third material formed on a second material on a surface of the substrate to a modifying agent to allow an inhibitor contained in the modifying agent to be adsorbed on a surface of the first material and (b) exposing the substrate to a reactant to allow at least a portion of the third material to react with the reactant to generate a reaction product; and
(c) applying energy to the substrate to perform removal of the reaction product and at least one selected from the group of removal and deactivation of the inhibitor in parallel.

2. The processing method of claim 1, wherein the reactant includes a first reactant and a second reactant that reacts with the first reactant, and
wherein (b) includes at least one selected from the group of alternately exposing the substrate to the first reactant and the second reactant and simultaneously exposing the substrate to the first reactant and the second reactant.

3. The processing method of claim 2, wherein the first reactant includes a halogen-containing material and the second reactant includes a reducing agent.

4. The processing method of claim 2, wherein the first reactant includes a fluorine-containing material and the second reactant includes hydrogen nitride.

5. The processing method of claim 2, wherein the first reactant contains fluorine and hydrogen, and the second reactant contains nitrogen and hydrogen.

6. The processing method of claim 1, wherein in (c), thermal energy is applied to the substrate.

7. The processing method of claim 1, wherein in (c), plasma energy is applied to the substrate.

8. The processing method of claim 1, wherein in (c), the substrate is heated to a temperature equal to or higher than a temperature of the substrate in (b) or a temperature higher than the temperature of the substrate in (b).

9. The processing method of claim 1, wherein in (c), the substrate is exposed to a remover that reacts with at least one selected from the group of the inhibitor and the reaction product.

10. The processing method of claim 1, wherein the third material contains an element which is the same as an element constituting the first material.

11. The processing method of claim 1, wherein both of the first material and the third material contain the same plurality of elements, the first material has a first composition, and the third material has a second composition different from the first composition.

12. The processing method of claim 11, wherein the first composition includes a stoichiometric composition, and the second composition includes a non-stoichiometric composition.

13. The processing method of claim 1, wherein a density of the third material is lower than a density of the first material.

14. The processing method of claim 1, wherein both of the first material and the third material contain a first element and a second element, and an atomic concentration of the second element contained in the third material is lower than an atomic concentration of the second element contained in the first material.

15. The processing method of claim 1, wherein a density of adsorption sites on a surface of the third material is lower than a density of adsorption sites on the surface of the first material.

16. The processing method of claim 1, wherein a density of hydroxyl group terminations on a surface of the third material is lower than a density of hydroxyl group terminations on the surface of the first material.

17. The processing method of claim 1, wherein the first material includes a thermal oxide film or a deposited oxide film, and the third material includes at least one selected from the group of a native oxide film and a chemical oxide film.

18. The processing method of claim 1, wherein in (a), the inhibitor contained in the modifying agent is further adsorbed on a surface of the third material.

19. The processing method of claim 18, wherein a density of the inhibitor adsorbed on the surface of the third material is lower than a density of the inhibitor adsorbed on the surface of the first material.

20. A method of manufacturing a semiconductor device, comprising the processing method of claim 1.

21. A processing apparatus, comprising:
a provider configured to provide a substrate;
an energy applier configured to apply energy to the substrate; and
a controller configured to be capable of controlling the provider and the energy applier so as to perform a process including:
removing a third material by performing a cycle a predetermined number of times, the cycle including:
providing the substrate subjected to processes including (a) exposing the substrate including a first material and the third material formed on a second material on a surface of the substrate to a modifying agent to allow an inhibitor contained in the modifying agent to be adsorbed on a surface of the first material and (b) exposing the substrate to a reactant to allow at least a portion of the third material to react with the reactant to generate a reaction product; and
(c) applying energy to the substrate to perform removal of the reaction product and at least one selected from the group of removal and deactivation of the inhibitor in parallel.

22. A non-transitory computer-readable recording medium storing a program that causes, by a computer, a processing apparatus to perform a process comprising:
removing a third material by performing a cycle a predetermined number of times, the cycle including:
providing a substrate subjected to processes including (a) exposing the substrate including a first material and the third material formed on a second material on a surface of the substrate to a modifying agent to allow an inhibitor contained in the modifying agent to be adsorbed on a surface of the first material and (b) exposing the substrate to a reactant to allow at least a portion of the third material to react with the reactant to generate a reaction product; and
(c) applying energy to the substrate to perform removal of the reaction product and at least one selected from the group of removal and deactivation of the inhibitor in parallel.
